(19) United States
(12) Patent Application Publication
(10) Pub. No.: US 2025/0031556 A1
(43) Pub. Date: Jan. 23, 2025

(54) DISPLAY DEVICE

(71) Applicant: Samsung Display Co., Ltd., Yongin-si (KR)

(72) Inventors: WOOYOUNG KIM, Yongin-si (KR); SU JEONG KIM, Yongin-si (KR); EUNBEE LEE, Yongin-si (KR); JUNG-WOO LEE, Yongin-si (KR); JINHYEONG LEE, Yongin-si (KR)

(73) Assignee: Samsung Display Co., Ltd., Yongin-si (KR)

(21) Appl. No.: 18/636,571

(22) Filed: Apr. 16, 2024

(30) Foreign Application Priority Data
Jul. 19, 2023 (KR) 10-2023-0093733

(51) Int. Cl. H10K 59/80; H10K 102/00

(52) U.S. Cl. CPC H10K 59/8792; H10K 59/879; H10K 2102/351

(57) ABSTRACT

A display device includes a display element layer including a light emitting element and a pixel defining layer including a pixel opening, and an optical layer on the display element layer. The optical layer includes a light blocking pattern, including a first light blocking part and a second light blocking part on the first light blocking part. The first light blocking part includes a first bottom surface spaced apart from the second light blocking part and a first side surface substantially perpendicular to the first bottom surface, and the second light blocking part includes a second bottom surface adjacent to the first light blocking part and a second side surface inclined with respect to the second bottom surface. An angle between the second bottom surface and the second side surface is greater than about 90° and less than or equal to about 160°.

### CROSS-REFERENCE TO RELATED APPLICATIONS

This application claims priority to and benefits of Korean Patent Application No. 10-2023-0093733 under 35 U.S.C. § 119, filed on Jul. 19, 2023 in the Korean Intellectual Property Office, the entire contents of which are incorporated herein by reference.

### BACKGROUND

### 1. Technical Field

The disclosure herein relates to a display device including an optical layer.

### 2. Description of the Related Art

Various display devices used in multimedia devices such as televisions, mobile phones, table computers, and game consoles are being developed. Such a display device may include various optical members to provide high-quality images and videos to users. Research on optical members to improve display quality and display efficiency in various types of display devices is in progress.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a display device with reduced external light reflection and improved display efficiency.

An embodiment provides a display device that may include a display element layer including a light emitting element and a pixel defining layer including a pixel opening; and an optical layer including a light blocking pattern, the light blocking pattern comprises a first light blocking part and a second light blocking part disposed on the first light blocking part, and disposed on the display element layer, wherein the first light blocking part includes a first bottom surface spaced apart from the second light blocking part and a first side surface substantially perpendicular to the first bottom surface, the second light blocking part includes a second bottom surface adjacent to the first light blocking part and a second side surface inclined with respect to the second bottom surface, and an angle between the second bottom surface and the second side surface is greater than about 90° and less than or equal to about 160°.

In an embodiment, a refractive index of the first light blocking part may be greater than a refractive index of the second light blocking part.

In an embodiment, a refractive index of the first blocking part may be about 1.8 or more and about 2.5 or less.

In an embodiment, a refractive index of the second light blocking part may be about 1.5 or more and less than about 1.8.

In an embodiment, an optical density (OD) of the first light blocking part may be greater than an optical density of the second light blocking part.

In an embodiment, an optical density of the first light blocking part may be about 1.5 or more and about 2.0 or less.

In an embodiment, an optical density of the second light blocking part may be about 1.0 or more and less than about 1.5.

In an embodiment, a sum of a first thickness of the first light blocking part and a second thickness of the second light blocking part may be about 0.5 μm or more and about 2.0 um or less.

In an embodiment, a ratio of a first thickness of the first light blocking part to a second thickness of the second light blocking part may be in a range of about 1:0.5 to about 1:2.0.

In an embodiment, the light emitting element may include a first electrode of which at least a portion is partially exposed in the pixel opening, a second electrode facing the first electrode, and an emission layer disposed between the first electrode and the second electrode, the light blocking pattern may include a first light blocking pattern overlapping the emission layer and a second light blocking pattern overlapping the pixel defining layer, and each of the first light blocking pattern and the second light blocking pattern may include the first light blocking part and the second light blocking part.

In an embodiment, on a plane, the first light blocking pattern may have a substantially circular or substantially square shape.

In an embodiment, the light blocking pattern may include a pattern opening, and the optical layer may further include a filter part comprising at least one of a pigment and a dye and filled into the pattern opening of the light blocking pattern.

In an embodiment, the display device may comprise an emission area and a non-emission area adjacent to the emission area, and the filter part in the emission area may cover the light blocking pattern.

In an embodiment, the filter part in the emission area may include a first portion overlapping the light blocking pattern and a second portion that does not overlap the light blocking pattern, and a first height of the first portion may be higher than a second height of the second portion in a thickness direction.

In an embodiment, a display device, which may include an emission area and a non-emission area adjacent to the emission area; and may include a display element layer including a light emitting element and a pixel defining layer including a pixel opening; and an optical layer including a first light blocking pattern in the emission area and a second light blocking pattern in the non-emission area, wherein each of the first light blocking pattern and the second light blocking pattern includes a first light blocking part and a second light blocking part disposed on the first light blocking part, and an optical density (OD) of the first light blocking part is greater than an optical density of the second light blocking part, and a refractive index of the first light blocking part is greater than a refractive index of the second light blocking part.

In an embodiment, the first light blocking part may include a first bottom surface spaced apart from the second light blocking part and a first side surface substantially perpendicular to the first bottom surface, the second light blocking part may include a second bottom surface adjacent to the first light blocking part and a second side surface inclined with respect to the second bottom surface, and an angle between the second bottom surface and the second side surface may be greater than about 90° and less than or equal to about 160°.

In an embodiment, the optical density of the first light blocking part may be about 1.5 or more and about 2.0 or less, and the optical density of the second light blocking part may be about 1.0 or more and less than about 1.5.

In an embodiment, the refractive index of the first light blocking part may be about 1.8 or more and about 2.5 or less, and the refractive index of the second light blocking part may be about 1.5 or more and less than about 1.8.

In an embodiment, the sum of a first thickness of the first light blocking part and a second thickness of the second light blocking part may be about 0.5 μm or more and about 2.0 um or less, and a ratio of the first thickness of the first light blocking part to the second thickness of the second light blocking part may be in a range of about 1:0.5 to about 1:2.0.

In an embodiment, the optical layer may further include a filter part comprising at least one of a pigment and a dye and covering the first light blocking pattern.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1 is a schematic perspective view of a display device according to an embodiment;

FIG. 2 is an exploded schematic perspective view of the display device according to an embodiment;

FIG. 3A is an enlarged schematic plan view of an area XX′ of FIG. 2;

FIG. 3B is a schematic plan view illustrating a portion of the display device according to an embodiment;

FIG. 4 is a schematic cross-sectional view illustrating a portion corresponding to line I-I′ of FIG. 2;

FIG. 5 is a schematic cross-sectional view illustrating a portion corresponding to line II-II′ of FIG. 3A;

FIG. 6 is an enlarged schematic cross-sectional view of an area YY′ of FIG. 5;

FIG. 7 is an enlarged schematic cross-sectional view of an area YY′-a of FIG. 6; and

FIG. 8 is a schematic cross-sectional view illustrating a portion of the display device according to an embodiment.

### DETAILED DESCRIPTION OF THE EMBODIMENTS

Since the disclosure may have diverse modified embodiments, embodiments are illustrated in the drawings and are described in the detailed description of the disclosure. However, this does not limit the disclosure within specific embodiments and it should be understood that the disclosure covers all the modifications, equivalents, and replacements within the idea and technical scope of the disclosure.

In this specification, it will also be understood that when one component (or region, layer, portion) is referred to as being ‘on’, ‘connected to’, or ‘coupled to’ another component, it can be directly disposed/connected/coupled on/to the one component, or an intervening third component may also be present.

It will be understood that the terms “connected to” or “coupled to” may include a physical or electrical connection or coupling.

Like reference numerals refer to like elements throughout. Also, in the figures, the thickness, ratio, and dimensions of components are exaggerated for clarity of illustration.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that although the terms such as ‘first’ and ‘second’ are used herein to describe various elements, these elements should not be limited by these terms. These terms are used only to distinguish one component from other components. For example, a first element referred to as a first element in an embodiment can be referred to as a second element in an embodiment without departing from the scope of the appended claims.

As used herein, the singular forms, “a,” “an,” and “the” are intended to include the plural forms as well, unless the context clearly indicates otherwise.

Also, “under”, “below”, “above’, “upper”, and the like are used for explaining relation association of the elements illustrated in the drawings. The terms may be a relative concept and described based on directions expressed in the drawings.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used herein have the same meaning as commonly understood by a person of ordinary skill in the art to which the disclosure belongs. In addition, terms such as terms defined in commonly used dictionaries should be interpreted as having a meaning consistent with the meaning in the context of the related technology, and will not be interpreted in an idealized or overly formal sense unless expressly so defined herein.

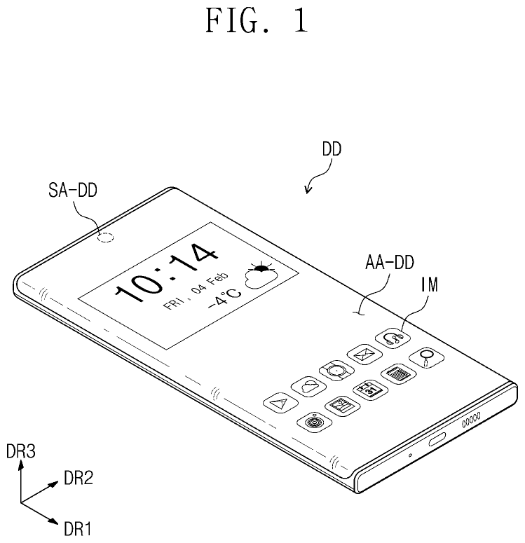

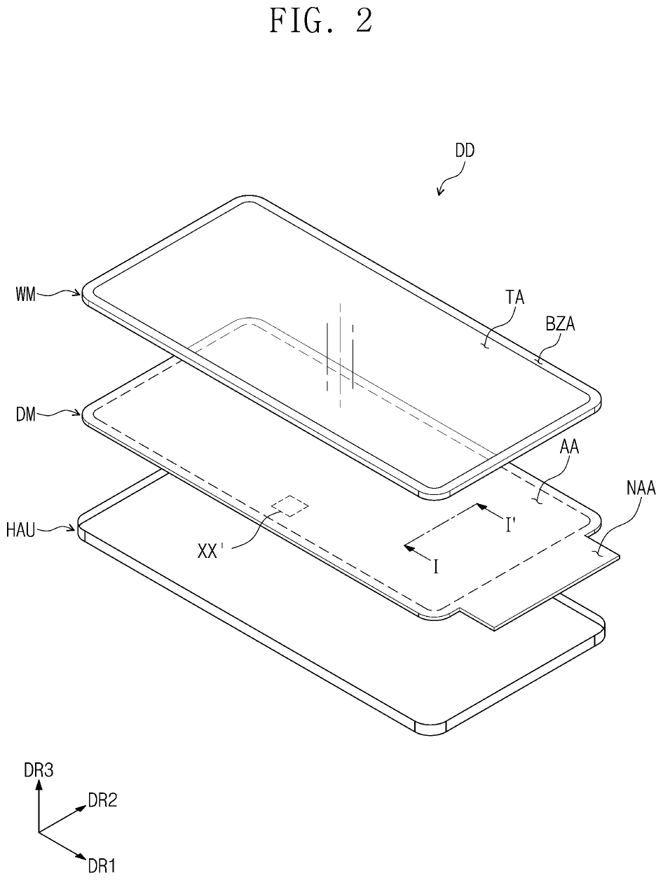

Hereinafter, a display device according to an embodiment will be described with reference to the accompanying drawings. FIG. 1 is a schematic perspective view of a display device according to an embodiment; FIG. 2 is an exploded schematic perspective view of the display device according to an embodiment.

Referring to FIG. 1, a display device DD may be a device that is activated according to an electrical signal. For example, the display device DD may be a mobile phone, a tablet PC, a car navigation system, a game console, or a wearable device, but the embodiment is not limited thereto. FIG. 1 illustrates an example in which the display device DD is a mobile phone.

The display device DD according to an embodiment may display an image IM through a display area AA-DD. The display area AA-DD may include a plane defined by a first directional axis DR1 and a second directional axis DR2. The display area AA-DD may include a curved surface that is bent from at least one side or a side of the plane defined by the first and second directional axes DR1 and DR2. The display device DD of FIG. 1 according to an embodiment is illustrated as including two curved surfaces that are bent from both sides of the plane defined by the first directional axis DR1 and the second directional axis DR2. However, the shape of the display area-AA-DD is not limited thereto. For example, the display area AA-DD may include only a plane defined by the first direction axis DR1 and the second direction axis DR2, and the display area AA-DD may further include at least two or more curved surfaces, for example, four curved surfaces, each of which is bent from four sides of the plane defined by the first directional axis DR1 and the second direction axis DR2.

The display device DD according to an embodiment may be a flexible display device. The “flexible” means a bendable property and may include a structure that is completely folded to a few nanometer. Also, the display device DD may be rigid.

A sensing area SA-DD may be defined in the display area AA-DD of the display device DD. Although FIG. 1 illustrates one sensor area SA as an example, the number of sensing areas SA-DD is not limited thereto. The sensing area SA-DD may be a portion of the display area AA-DD. The display device DD may display an image through the sensing area SA-DD.

An optical signal, for example, visible light or infrared light may move to the sensing area DA-DD. The display device DD may include an electronic module that photographs an external image through the visible light passing through the sensing area SA-DD or determines accessibility of an external object through the infrared light.

The first to third directional axes DR1 to DR3 are illustrated in FIG. 1 and following drawings, and directions indicated by the first to third directional axes DR1, DR2, and DR3, which are described in this specification, may be relative concepts and thus may be changed into different directions. Also, directions indicated by the first to third direction axes DR1, DR2, and DR3 may be described as first to fourth directions, and the same reference numerals may be used. In this specification, the first directional axis DR1 and the second directional axis DR2 may be perpendicular to each other, and the third directional axis DR3 may be a normal direction with respect to the plane defined by the first directional axis DR1 and the second directional axis DR2.

A thickness direction of the display device DD may be parallel to the third direction DR3. In this specification, a top surface (or, front surface, upper portion, and upper side) and a bottom surface (or rear surface) of each of members constituting the display device DD may be defined based on the third directional axis DR3. The top surface (or front surface, upper portion, upper side) refers to the direction (or surface) in which the image IM is displayed, and the bottom surface (or rear surface, lower portion, lower side) refers to a direction (or surface) opposite to the direction (or surface) in which the image IM is displayed. The cross-section refers to a surface parallel to the thickness direction DR3, and the plane refers to a surface perpendicular to the thickness direction DR3. The plane refers to the plane defined by the first direction axis DR1 and the second direction axis DR2.

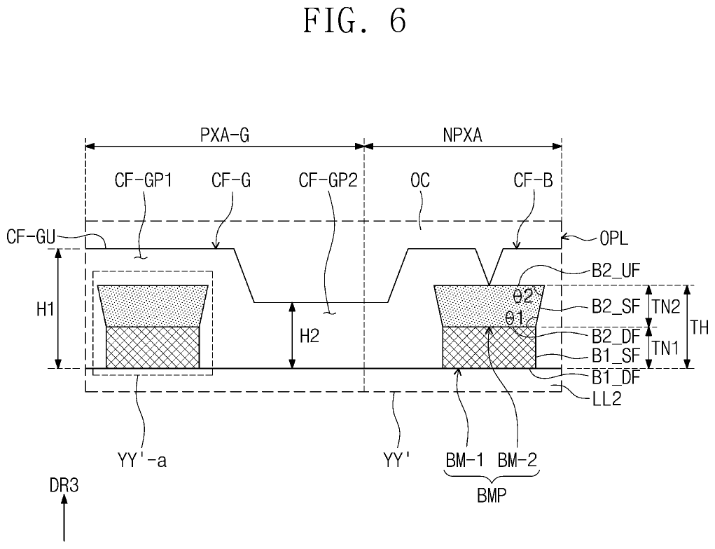

Referring to FIG. 6A, the display device DD may include a display module DM and a window WM disposed on the display module DM. The display device DD may further include a housing HAU.

The housing HAU may include a material having relatively high rigidity. For example, the housing HAU may include a frame and/or plate made of glass, plastic, or a metal. The housing HAU may provide a selectable accommodation space. The display panel DP may be accommodated in the accommodation space and protected from an external impact.

The window WM may cover the entire outside of the display module DM. The window WM may include a transmission area TA and a bezel area BZA. A front surface of the window WM including the transmission area TA and the bezel area BZA may correspond to the front surface of the display device DD. The transmission area TA may correspond to an active area AA of the display module DM, and the bezel area BZA may correspond to a peripheral area NAA of the display module DM. The bezel area BZA may define a shape of the transmission area TA. The bezel area BZA may be disposed adjacent to the transmission area TA to surround the transmission area TA. However, the embodiment is not limited thereto, and the bezel area BZA may be disposed adjacent to only one side or a side of the transparent area TA, or a portion of the bezel area BZA may be omitted.

The transmission area TA may be an optically transparent area. The bezel area BZA may be an area HA having light transmittance that is relatively less than that of the transmission area TA. The bezel area BZA may have a selectable color.

The display Module DM may be a constituent that generates an image and senses an input applied from the outside. The display module DM may be defined into the active area AA and the peripheral area NAA. The active area AA may be an area that is activated according to an electrical signal. The peripheral area NAA may be an area disposed adjacent to at least one side or a side of the active area AA. The peripheral area NAA may be disposed to surround the active area AA. However, the embodiment is not limited thereto, and unlike the example illustrated in FIG. 2, a portion of the peripheral area NAA according to an embodiment may be omitted. A driving circuit or a driving line for driving the active area AA may be disposed in the peripheral area NAA.

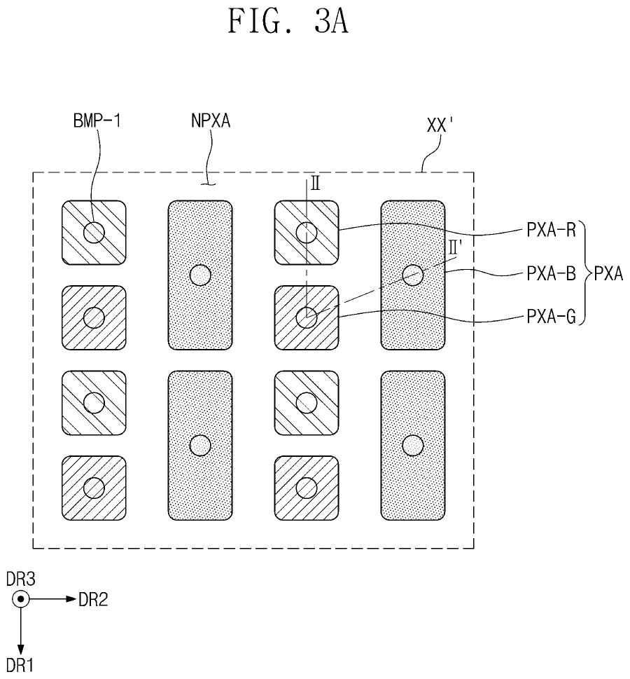

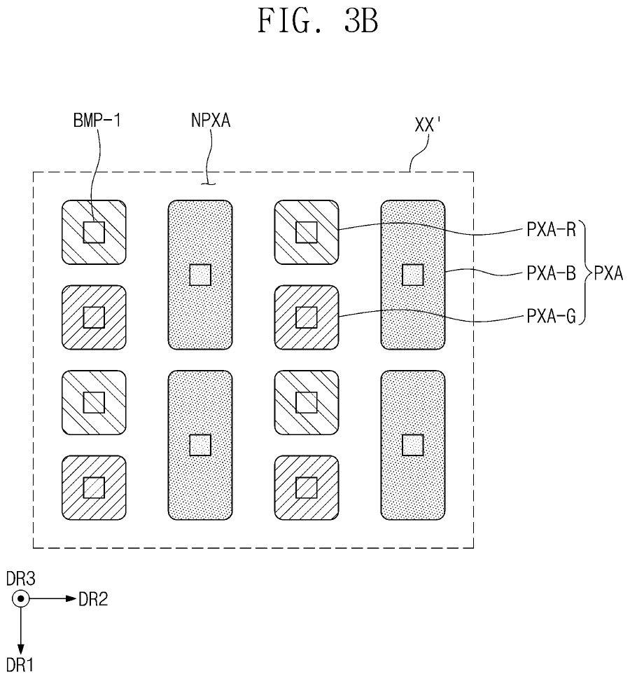

FIG. 3A is an enlarged schematic plan view of an area XX′ of FIG. 2. FIG. 3A illustrates a schematic plan view of the active area AA of FIG. 2.

Referring to FIG. 3A, the display module DM (see FIG. 2) may include an emission area PXA and a non-emission area NPXA. FIG. 3A illustrates that the emission area PXA is arranged (or disposed) in an S-stripe shape. First to third emission areas PXA-R, PXA-G, and PXA-B may be distinguished from each other so as not to overlap each other when viewed on a plane. The non-emission area NPXA may be disposed between the neighboring emission areas PXA-R, PXA-G, and PXA-B.

The emission area PXA may include a first emission area PXA-R, a second emission area PXA-G, and a third emission area PXA-B. The first emission area PXA-R may emit first light, the second emission area PXA-G may emit second light different from the first light, and the third emission area PXA-B may emit third light different from each of the first light and the second light. In an embodiment, the first pixel area PXA-R may be a red emission area that emits red light, the second pixel area PXA-G may be a green emission area that emits green light, and the third pixel area PXA-B may be a blue emission area that emits blue light.

The first emission area PXA-R may be disposed in a first row, the second emission area PXA-G may be disposed in a second row, and the third emission area PXA-B may be disposed to overlap the first and second rows. The first emission area PXA-R and the second emission area PXA-G may be alternately arranged in the first row, and the third emission area PXA-B may be arranged in the second row. A surface area of the third emission area PXA-B disposed to overlap the first row and the second row may be larger than that of the first emission area PXA-R and that of the second emission area PXA-G.

On the plane, the surface areas of the first to third emission areas PXA-R, PXA-G, and PXA-B may be different from each other. For example, the surface area of the first emission area PXA-R and the surface area of the second emission area PXA-G may be substantially the same, and the surface area of the third emission area PXA-B may be greater than that of the first emission area PXA-R and that of the second emission area PXA-G. However, the embodiment is not limited to this, and a surface area ratio of the first to third emission areas PXA-R, PXA-G, and PXA-B may be variously adjusted depending on display quality characteristics required for the display device DD. In this specification, substantially the same may include a case in which physical values are the same and a case in which there is a difference within an error range in the process.

Shapes of the first to third emission areas PXA-R, PXA-G, and PXA-B on the plane may also be modified in various manners. In FIG. 3A, each of the first to third emission areas PXA-R, PXA-G, and PXA-B is illustrated as having a square shape on the plane, but the embodiment is not limited thereto. Each of the first to third emission areas PXA-R, PXA-G, and PXA-B may have a shape such as a polygon or a circle on the plane.

FIG. 3A illustrates the emission area PXA, the non-emission area NPXA, and a first light blocking pattern BMP-1, and other components are omitted for convenience of explanation. Referring to FIG. 3A, the first light blocking pattern BMP-1 may overlap the emission area PXA. Each of the first to third emission areas PXA-R, PXA-G, and PXA-B may overlap the first light blocking pattern BMP-1. A surface area of the first light blocking pattern BMP-1 on the plane may be less than that of each of the first to third emission areas PXA-R, PXA-G, and PXA-B. In this specification, the overlap of one component with another component is not limited to the case of the same surface area and the same shape, but also includes the case of a different surface area and/or a different shape.

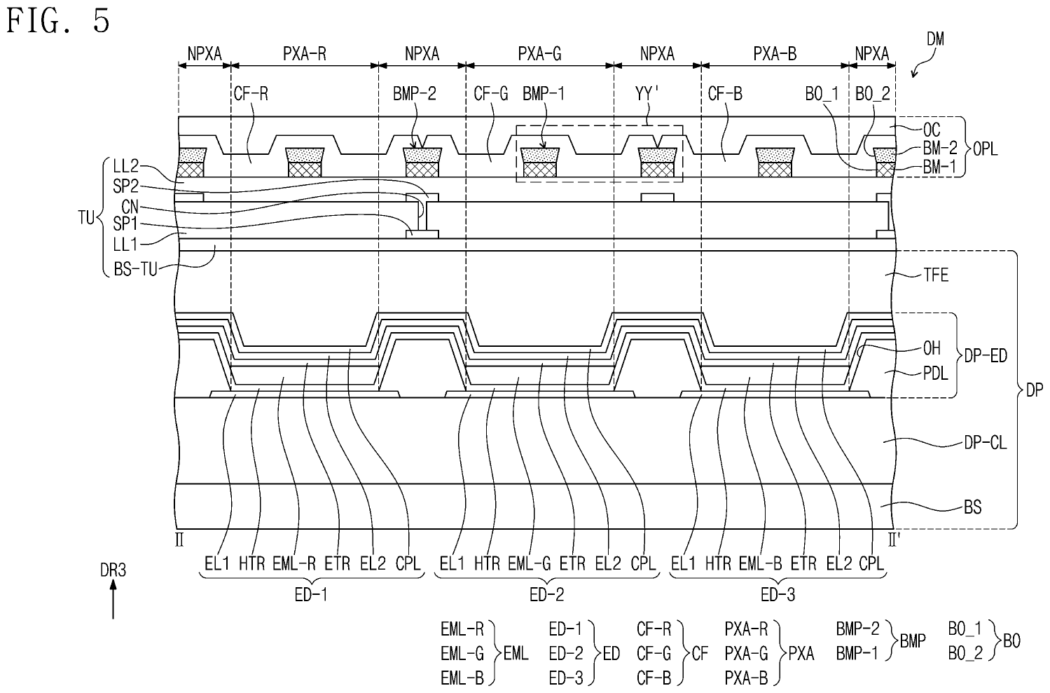

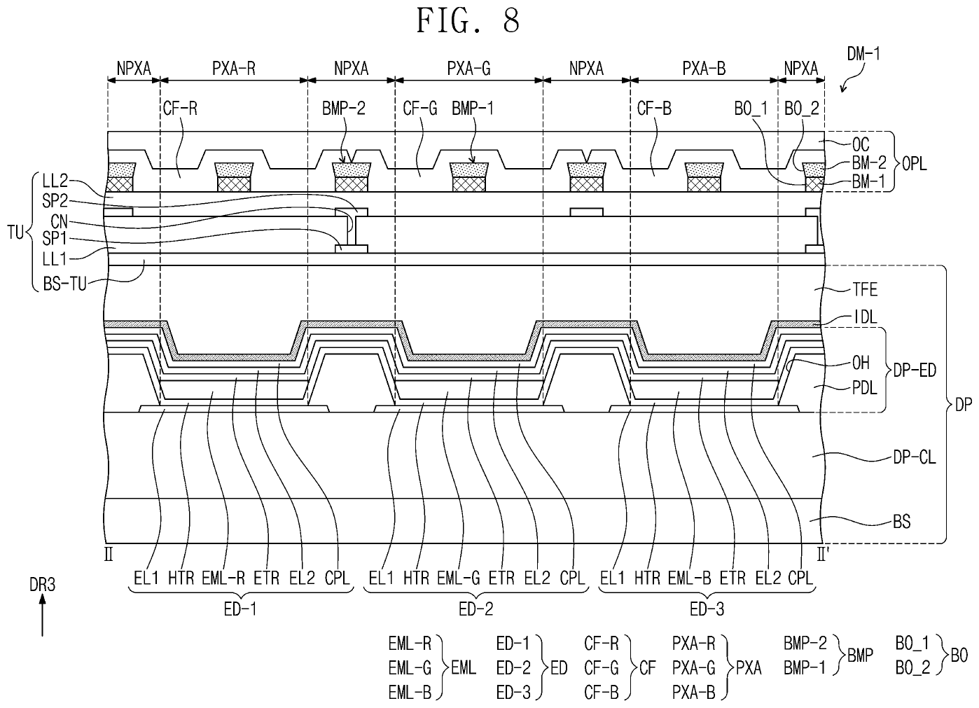

The first light blocking pattern BMP-1 may not overlap the non-emission area NPXA. On the plane, the first light blocking pattern BMP-1 may have a circular shape. The first light blocking pattern BMP-1 may be provided in the optical layer OPL (see FIGS. 5 and 8) to be described later, and the display device DD (see FIG. 2) including the first light blocking pattern BMP-1 may reduce the reflection of the external light and improve the display efficiency. The first light blocking pattern BMP-1 will be described in more detail later.

FIG. 3B is a schematic plan view according to an embodiment. FIG. 3B is a schematic plan view of an area XX′ according to an embodiment. In the description of FIG. 3B, contents that overlap the content described with reference to FIGS. 1 to 3A will not be described, and the differences will be explained.

In case that compared to FIG. 3A, FIG. 3B illustrates a difference in only a shape of the first light blocking pattern BMP-1. Referring to FIG. 3B, the first light blocking pattern BMP-1 may have a substantially square shape on the plane.

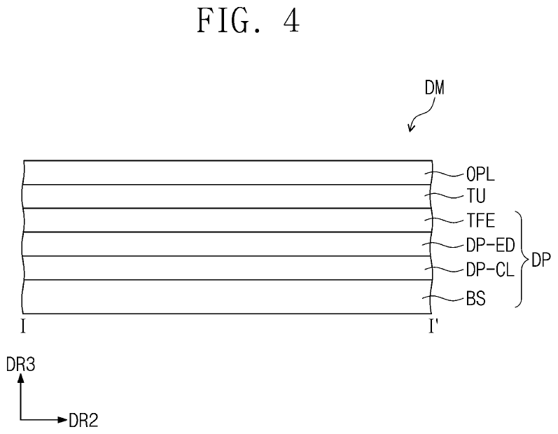

FIG. 4 is a schematic cross-sectional view illustrating a portion corresponding to line I-I′ of FIG. 2. FIG. 4 is a schematic cross-sectional view illustrating a configuration of the display module DM.

Referring to FIG. 4, the display module DM may include a display panel DP and an optical layer OPL disposed on the display panel DP. The display module DM may further include a sensor layer TU disposed on the display panel DP. The sensor layer TU may be disposed between the display panel DP and the optical layer OPL.

The display panel DP may be configured to actually generate an image. The display panel DP may include a base layer BS, a circuit layer DP-CL, a display element layer DP-ED, and an encapsulation layer TFE, which are sequentially laminated. Unlike shown, a functional layer may be further disposed between two adjacent layers of the base layer BS, the circuit layer DP-CL, the display element layer DP-ED, and the encapsulation layer TFE.

The base layer BS may provide a base surface on which the circuit layer DP-CL is disposed. The base layer BS may be a flexible substrate capable of being bent, folded, or rolled. The base layer BS may be a glass substrate, a metal substrate, or a polymer substrate. However, the embodiment is not limited thereto. For example, the base layer BS may include an inorganic layer, an organic layer, or a composite layer.

The circuit layer DP-CL may be disposed on the base layer BS. The circuit layer DP-CL may include an insulating layer, a semiconductor pattern, a conductive pattern, and a signal line. The insulating layer, the semiconductor layer, and the conductive layer may be formed above the base layer BS in a manner such as coating or vapor deposition, and then, the insulating layer, the semiconductor layer, and the conductive layer may be selectively patterned through photolithography processes. Thereafter, the semiconductor pattern, the conductive pattern, and the signal line included in the circuit layer DP-CL may be provided.

The display element layer DP-ED may be disposed on the circuit layer DP-CL. The display element layer DP-ED may include a light emitting element ED (see FIG. 5). For example, the light emitting element ED (see FIG. 5) may include an organic light emitting material, an inorganic light emitting material, an organic-inorganic light emitting material, a quantum dot, a quantum rod, a micro LED, or a nano LED.

The encapsulation layer TFE may be disposed on the display element layer DP-ED. The encapsulation layer TFE may protect the display element layer DP-ED against foreign substances such as moisture, oxygen, and dust particles. The encapsulation layer TFE may include at least one inorganic layer. The encapsulation layer TFE may include an inorganic layer, an organic layer, and an inorganic layer, which are sequentially laminated.

The sensor layer TU may be directly disposed on the encapsulation layer TFE. By way of example, an adhesive member may be disposed between the sensor layer TU and the display panel DP.

In this specification, that one component is directly disposed on another component means that a third component is not placed between one component and another component. In case that one component is “directly placed” on another component, it means that one component is “in contact with” another component.

The sensor layer TU may detect an external input, change the external input into a selectable input signal, and provide the input signal to the display panel DP. For example, the sensor layer TU may be a touch sensing layer that detects touch. The sensor layer TU may recognize user's direct touch, user's indirect touch, object's direct touch, or object's indirect touch.

The sensor layer TU may detect at least one of the position of the touch and an intensity (pressure) of the touch applied from the outside. The sensor layer TU may have various structures or be made of various materials, and is not limited to any one embodiment. For example, the sensor layer TU may detect an external input using a capacitance manner. The display panel DP may receive an input signal from the sensor layer TU and generate an image corresponding to the input signal.

The optical layer OPL may be disposed on the sensor layer TU. The optical layer OPL may include a light blocking pattern BMP (see FIG. 5), which will be described later. The light blocking pattern BMP (see FIG. 5) may include a first light blocking part BM-1 (see FIG. 5) and a second light blocking part BM-2 (see FIG. 5) disposed on the first light blocking part BM-1 (FIG. 5). Thus, the display device DD (see FIG. 2) including the optical layer OPL may exhibit excellent display quality by reducing external light reflection and improving display efficiency. The optical layer OPL will be described in more detail later.

FIG. 5 is a schematic cross-sectional view illustrating a portion corresponding to line II-II′ of FIG. 3A. FIG. 5 is a schematic cross-sectional view illustrating a configuration of the display module DM.

The base layer BS may include a single layer or multiple layers. For example, the base layer BS may include a first synthetic resin layer, an intermediate layer with the multi-layer or single-layer structure, and a second synthetic resin layer, which are sequentially laminated. The intermediate layer may be referred to as a base barrier layer. The intermediate layer may include, but is not particularly limited to, a silicon oxide (SiOₓ) layer and an amorphous silicon (a-Si) layer disposed on the silicon oxide layer. For example, the intermediate layer may include at least one of a silicon oxide layer, a silicon nitride layer, a silicon oxy nitride layer, or an amorphous silicon layer.

Each of the first and second synthetic resin layers may include a polyimide-based resin. Also, each of the first and second synthetic resin layers may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin. In this specification, the “˜˜”-based resin means as including a functional group of “˜˜”.

The circuit layer DP-CL may be disposed on the base layer BS. The circuit layer DP-CL may include transistors (not shown). The transistors (not shown) may include a control electrode, an input electrode, and an output electrode, respectively. For example, the circuit layer DP-CL may include a switching transistor and a driving transistor for driving the light emitting element ED of the display element layer DP-ED.

The display element layer DP-ED may include a light emitting element ED and a pixel defining layer PDL. The light emitting element ED may include first to third light emitting elements ED-1, ED-2, and ED-3. The first light emitting element ED-1 corresponds to the first emission area PXA-R, the second light emitting element ED-2 corresponds to the second emission area PXA-G, and the third light emitting element ED-3 may correspond to the third emission area PXA-B.

Each of the first to third light emitting elements ED-1, ED-2, and ED-3 may include a first electrode EL1, a second electrode EL2 disposed on the first electrode EL1, and an emission layer EML disposed between the first electrode EL1 and the second electrode EL2. The emission layer EML may include first to third emission layers EML-R, EML-G, and EML-B. Each of the first to third light emitting elements ED-1, ED-2, and ED-3 may include a hole transport region HTR disposed between the first electrode EL1 and the emission layer EML and an electron transport region ETR disposed between the emission layer EML and the second electrode EL2. Each of the first to third light emitting elements ED-1, ED-2, and ED-3 may further include a capping layer CPL disposed on the second electrode EL2.

The pixel defining layer PDL may have pixel openings OH, which are defined therein. At least a portion of the first electrode EL1 may be exposed through the pixel openings OH. The pixel openings OH defined in the pixel defining layer PDL may respectively correspond to the emission areas PXA-R, PXA-G, and PXA-B. The non-emission area NPXA may be an area between the emission areas PXA-R, PXA-G, and PXA-B adjacent to each other and may correspond to the pixel defining layer PDL.

The pixel defining layer PDL may include an organic or inorganic material. For example, the pixel defining layer PDL may be made of a polyacrylate-based resin, a polyimide-based resin, silicon nitride (SiNₓ), silicon oxide (SiOₓ), or silicon nitride (SiOₓN_{y}).

The pixel defining layer PDL may have a property of absorbing light and, for example, may display a black color. The pixel defining layer PDL may include a black coloring agent. A black component may include a black dye or a black pigment. The pixel defining layer PDL may have light blocking characteristics.

FIG. 5 illustrates an embodiment, in which the emission layers EML-R, EML-G, and EML-B of the light emitting elements ED-1, ED-2, and ED-3 may be disposed in the pixel opening OH defined in the pixel defining layer PDL, and the hole transport region HTR, the electron transport region ETR, the second electrode EL2, and the capping layer CPL are provided as a common layer in all of the light emitting elements ED-1, ED-2, and ED-3. However, the embodiment is not limited to this, and unlike FIG. 5, at least one of the hole transport region HTR, the electron transport region ETR, the second electrode EL2, and the capping layer CPL may be provided to be patterned inside the pixel opening OH defined in the defining layer PDL. The hole transport region HTR, the emission layer EML-R, EML-G, and EML-B, the electron transport region ETR, and the second electrode EL2, and the capping layer CPL of the light emitting elements ED-1, ED-2, and ED-3 may be provided by being patterned using an inkjet printing method.

The first electrode EL1 may be an anode or a cathode. Also, the first electrode EL1 may be a pixel electrode. The first electrode EL1 may be made of a metal material, a metal alloy, or a conductive compound. The first electrode EL1 may be a transmissive electrode, a transflective electrode, or a reflective electrode. The first electrode EL1 may be a transmissive electrode, a transflective electrode, or a reflective electrode. The first electrode EL1 may include at least one selected from Ag, Mg, Cu, Al, Pt, Pd, Au, Ni, Nd, Ir, Cr, Li, Ca, LiF, Mo, Ti, W, In, Sn, and Zn, two or more kinds of compounds selected from the above-described materials, a mixture of two or more kinds of above-described materials, or oxides thereof.

In case that the first electrode EL1 is the transmissive electrode, the first electrode EL1 may be formed of metal oxide, for example, indium tin oxide (ITO), indium zinc oxide (IZO), zinc oxide (ZnO), or indium tin zinc oxide (ITZO). In case that the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (laminated structure of LiF and Ca), LiF/Al (laminated structure of LiF and Al), Mo, Ti, or a compound or mixture (for example, a mixture of Ag and Mg) thereof. By way of example, the first electrode EL1 may have a multiple layer structure including the reflective layer or transflective layer, which is made of the above-described material, indium tin oxide (ITO), indium zinc oxide (IZO), zinc oxide (ZnO), or indium tin zinc oxide (ITZO). For example, the first electrode EL1 may have a three-layer structure of ITO/Ag/ITO, but is not limited thereto.

The hole transport region HTR may include at least one of a hole injection layer, a hole transport layer, or an electron blocking layer. The hole transport region HTR may include a hole transport material and/or a hole injection material.

The first light emitting element ED-1 may include a first emission layer EML-R overlapping the first emission area PXA-R, and the second light emitting element ED-2 may include a second emission area EML-G overlapping the second emission area PXA-G. The third light emitting element ED-3 may include a third emission layer EML-B overlapping the third emission area PXA-B.

The first emission layer EML-R may overlap the first emission area PXA-R and may emit first light. The second emission layer EML-G may overlap the second emission area PXA-G and may emit second light. The third emission layer EML-B may overlap the third emission area PXA-B and may emit third light. The first to third light may be light having different wavelength ranges. For example, the first light may be red light having a wavelength range of about 625 nm to about 675 nm, the second light may be green light having a wavelength range of about 500 nm to about 570 nm, and the third light may be blue light having a wavelength range of about 410 nm to about 480 nm.

The electron transport region ETR may include at least one of an electron injection layer, an electron transport layer, and a hole stop layer. The electron transport region ETR may include electron transport material and/or electron injection material.

The second electrode EL2 may be a common electrode. The second electrode EL2 may be a cathode or an anode, but this embodiment is not limited thereto. For example, in case that the first electrode EL1 is the anode, the second electrode EL2 may be the cathode, and in case that the first electrode EL1 is the cathode, the second electrode EL2 may be the anode. The second electrode EL2 may be a transmissive electrode, a transflective electrode, or a reflective electrode. In case that the second electrode EL2 is the transmissive electrode, the second electrode EL2 may be made of metal oxide, for example, indium tin oxide (ITO), indium zinc oxide (IZO), zinc oxide (ZnO), or indium tin zinc oxide (ITZO).

In case that the second electrode EL2 is the transflective electrode or reflective electrode, the second electrode EL2 may include g, Mg, Cu, Al, Pt, Pd, Au, Ni, Nd, Ir, Cr, Li, Ca, LiF/Ca, LiF/Al, Mo, Ti, Yb, W, or a compound or mixture (for example, AgMg, AgYb, or MgYb) thereof. By way of example, the second electrode ED2 may have a multiple layer structure including the reflective layer or transflective layer, which is made of the above-described material, indium tin oxide (ITO), indium zinc oxide (IZO), zinc oxide (ZnO), or indium tin zinc oxide (ITZO). For example, the second electrode EL2 may include the above-described metal material, a combination of two or more metal materials selected from the above-described metal materials, or oxide of the above-described metal materials.

The capping layer CPL may include multiple layers or a single layer. In an embodiment, the capping layer CPL may be an organic layer or an inorganic layer. For example, in case that the capping layer CPL may include the inorganic material, the inorganic material may include an alkali metal compound such as LiF, an alkaline earth metal compound such as MgF₂, SiON, SiNₓ, SiO_{y}, or the like within the spirit and scope of the disclosure. For example, in case that the capping layer CPL includes the organic material, the organic material may include α-NPD, NPB, TPD, m-MTDATA, Alq₃, CuPc, N4,N4,N4′,N4′-tetra (biphenyl-4-yl) biphenyl-4,4′-diamine (TPD15), 4,4′,4″-Tris(carbazol-9-yl) triphenylamine (TCTA), or the like, and may include an epoxy resin, or acrylic such as methacrylate. However, this embodiment is not limited thereto.

For example, the capping layer CPL may have a refractive index of about 1.6 or more. By way of example, the capping layer CPL may have a refractive index of about 1.6 or more for light having a wavelength range of about 550 nm or more and about 660 nm or less.

The encapsulation layer TFE may include at least one organic layer or inorganic layer or may include an organic layer and an inorganic layer. The encapsulation layer TFE may include a thin film encapsulation layer structure including at least one organic layer and at least one inorganic layer. For example, the structure of the encapsulation layer TFE may be a structure in which organic and inorganic layers are alternately laminated, or inorganic films, organic films and inorganic films are sequentially laminated. The encapsulation layer TFE may serve to protect the light emitting element ED from moisture and/or oxygen and protect the light emitting element ED from foreign substances such as dust particles.

The inorganic layer included in the encapsulation layer TFE may include, for example, a silicon nitride layer, a silicon oxy nitride layer, a silicon oxide layer, a titanium oxide layer, or an aluminum oxide layer, but is not limited thereto. The organic layer included in the encapsulation layer TFE may include, but is not limited to, an acrylic-based organic layer.

The sensor layer TU may include a sensor base layer BS-TU, a first conductive layer SP1, a first insulating layer LL1, a second conductive layer SP2, and a second insulating layer LL2. The first conductive layer SP1 may be disposed on the sensor base layer BS-TU. The first insulating layer LL1 may cover the first conductive layer SP1 and may be disposed on the sensor base layer BS-TU and the first conductive layer SP1. The second conductive layer SP2 may be disposed on the first insulating layer LL1. The second insulating layer LL2 may cover the second conductive layer SP2 and may be disposed on the first insulating layer LL1 and the second conductive layer SP2.

The sensor base layer BS-TU may be an inorganic layer containing at least one of silicon nitride, silicon oxynitride, or silicon oxide. By way of example, the sensor base layer BS-TU may be an organic layer including an epoxy resin, an acrylic resin, or an imide-based resin. Each of the sensor base layer BS-TU may have a single-layered structure or a multilayered structure in which layers are laminated in the third direction DR3. The sensor base layer BS-TU may be disposed directly on the encapsulation layer TFE. Unlike the drawings, the sensor base layer BS-TU may be omitted.

Each of the first conductive layer SP1 and the second conductive layer SP2 may have a single-layered structure or a multi-layered structure in which layers are laminated in the third directional axis DR3. Each of the single-layered conductive layers SP1 and SP2 may include a metal layer or a transparent conductive layer. The metal layer may include molybdenum, silver, titanium, copper, aluminum, or an alloy thereof. The transparent conductive layer may include transparent conductive oxide such as indium tin oxide (ITO), indium zinc oxide (IZO), zinc oxide (ZnO), indium zinc tin oxide (IZTO), and the like within the spirit and scope of the disclosure. Also, the transparent conductive layer may include a conductive polymer such as PEDOT, a metal nanowire, graphene, and the like within the spirit and scope of the disclosure.

The multilayered conductive layers SP1 and SP2 may include metal layers. The metal layers may have, for example, a three-layered structure of titanium (Ti)/aluminum (Al)/titanium (Ti). The multilayered conductive layers SP1 and SP2 may include at least one metal layer and at least one transparent conductive layer.

A contact hole CN may be defined in the first insulating layer LL1. The first conductive layer SP1 and the second conductive layer SP2 may be electrically connected through the contact hole CN. The contact hole CN may be filled with the material of the second conductive layer SP2.

Each of the first insulating layer LL1 and the second insulating layer LL2 may be an inorganic insulating layer or an organic insulating layer. The inorganic insulating layer may include at least one of oxide, titanium oxide, silicon oxide, silicon oxynitride, zirconium oxide, or hafnium oxide. The organic insulating layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyimide-based resin, a polyamide-based resin, or a perylene-based resin.

In an embodiment, the optical layer OPL may include a light blocking pattern BMP. The light blocking pattern BMP may include a first light blocking pattern BMP-1 and a second light blocking pattern BMP-2. The first blocking pattern BMP-1 may overlap the emission area PXA, and the second blocking pattern BMP-2 may overlap the non-emission area NPXA. The first light blocking pattern BMP-1 may overlap the emission layer EML, and the second light blocking pattern BMP-2 may overlap the pixel defining layer PDL.

Each of the first light blocking pattern BMP-1 and the second light blocking pattern BMP-2 may include a first light blocking part BM-1 and a second light blocking part BM-2 disposed on the first light blocking part BM-1. The second light blocking part BM-2 may be disposed directly on the first light blocking part BM-1. Each of the first light blocking part BM-1 and the second light blocking part BM-2 may include an organic light blocking material and/or an inorganic light blocking material. The light blocking material included in the first light blocking part BM-1 and the second light blocking part BM-2 may be used without limitation as long as the light blocking material satisfies the optical properties described below. The first light blocking part BM-1 and the second light blocking part BM-2 may have different optical characteristics.

A refractive index of the first light blocking part BM-1 may be greater than that of the second light blocking part BM-2. The refractive index of the first light blocking part BM-1 may be about 1.8 or more and about 2.5 or less. The refractive index of the second light blocking part BM-2 may be about 1.5 or more and less than about 1.8. For example, a difference between the refractive index of the first light blocking part BM-1 and the second light blocking part BM-2 may be about 0.1 or more.

The optical density OD of the first light blocking part BM-1 may be greater than that of the second light blocking part BM-2. An optical density of the first light blocking part BM-1 may be about 1.5 or more and about 2.0 or less. An optical density of the second light blocking part BM-2 may be about 1.0 or more and less than about 1.5.

The light blocking pattern BMP including the first light blocking part BM-1 and the second light blocking part BM-2, which satisfy the above-described refractive index and optical density, may absorb light entering from the outside of the display device DD (see FIG. 1) and transmit the light (for example, first to third light) emitted from the emission layer EML to improve display quality of the display device DD (see FIG. 1). The display device DD (FIG. 1) including the light blocking pattern BMP may exhibit excellent display quality by reducing the external light reflection and improving the display efficiency.

The light blocking pattern BMP may have a pattern opening (BO) defined therein. The pattern opening BO may include a first pattern opening BO_1 defined in the first light blocking part BM-1 and a second pattern opening BO_2 defined in the second light blocking part BM-2. On the plane, the first light blocking part BM-1 of the first light blocking pattern BMP-1 and the first light blocking part BM-1 of the second light blocking pattern BMP-2 may have an integrated shape. On the plane, the second light blocking part BM-2 of the first light blocking pattern BMP-1 and the second light blocking part BM-2 of the second light blocking pattern BMP-2 may have an integrated shape.

In an embodiment, the optical layer OPL may further include a filter part CF containing at least one of pigment or dye. The filter part CF may be disposed to be filled into the pattern opening BO. In the emission area PXA, the filter part CF may cover the first light blocking pattern BMP-1.

The filter part CF may include a first filter CF-R that transmits the first light, a second filter CF-G that transmits the second light, and a third filter CF-B that transmits the third light. The first filter CF-R may overlap the first emission layer EML-R, the second filter CF-G may overlap the second emission layer EML-G, and the third filter CF-B may overlap the third emission layer EML-B. For example, the first filter CF1 may be a red filter, the second filter CF2 may be a green filter, and the third filter CF3 may be a blue filter.

Each of the first to third filters CF-R, CF-G, and CF-B may include a polymer photosensitive resin and a pigment or dye. The first filter CF-R may include a red pigment or red dye, the second filter CF-G may include a green pigment or green dye, and the third filter CF-B may include a blue pigment or blue dye. However, the example is not limited to this, and the third filter CF-B may not include the pigment or dye. For example, the third filter CF-B may be made of transparent photoresist, and the third filter CF-B may be transparent. In case that the third filter CF-B is made of transparent photoresist, the light transmitted through the third filter CF-B is not limited to the third light.

Referring to FIG. 5, the optical layer OPL may further include an overcoat layer OC. The overcoat layer OC may be a planarization layer including an organic material. The overcoat layer OC may be optically transparent.

FIG. 6 is an enlarged schematic cross-sectional view of an area YY′ of FIG. 5. Referring to FIG. 6, the second filter CF-G may cover the light blocking pattern BMP on the second emission area PXA-G. In the second emission area PXA-G, the second filter CF-G may include portions with different heights. A top surface CF-GU of the second filter CF-G may be uneven.

In the second emission area PXA-G, the second filter CF-G may include a first portion CF-GP1 overlapping the light blocking pattern BMP and a second portion CF-GP2 that does not overlap the light blocking pattern BMP. A first height H1 of the first portion CF-GP1 overlapping the light blocking pattern BMP may be different from a second height H2 of the second portion CF-GP2 that does not overlap the light blocking pattern BMP. In the thickness direction DR3, the first height H1 of the first portion CF-GP1 overlap the light blocking pattern BMP may be higher than the second height H2 of the second portion CF-GP2 that does not overlap the light blocking pattern BMP. Each of the first height H1 and the second height H2 may be a height from the bottom surface of the optical layer OPL to the top surface CF-GU of the second filter CF-G. A bottom surface of the optical layer OPL may be a surface on which the first bottom surface B1_DF of the first light blocking part BM-1 is disposed. A portion of the light blocking patterns BMP (for example, the first light blocking pattern BMP-1 (see FIG. 5)) may be disposed to overlap the emission area PXA (see FIG. 5), and thus, in the emission area PXA (see FIG. 5), the second filter CF-G covering the light blocking pattern BMP may include the first portion CF-GP1 and the second portion CF-GP2, which have heights different from each other. Although the second filter CF-G has been described as an example, the same explanation may be applied to the first filter CF-R (see FIG. 5) and the third filter CF-B (scc FIG. 5).

The first light blocking part BM-1 may include a first bottom surface B1_DF and a first side surface B1_SF substantially perpendicular to the first bottom surface B1_DF. The first side surface B1_SF may be substantially perpendicular to the first bottom surface B1_DF. That is substantially vertical may include a case in which an angle between the first bottom surface B1_DF and the first side surface B1_SF is about 90° and a case an angle between the first bottom surface B1_DF and the first side surface B1_SF is close to about 90° within the error range of the process.

The first bottom surface B1_DF may be adjacent to the second insulating layer LL2 and spaced apart from the second light blocking part BM-2. In the cross section, the first light blocking part BM-1 may have a rectangular shape.

The second light blocking part BM-2 may include a second bottom surface B2_DF, a top surface B2_UF spaced apart from the second bottom surface B2_DF in the thickness direction DR3, and a second side surface B2_SF disposed between the second bottom surface B2_DF and the top surface B2_UF. The second bottom surface B2_DF may be adjacent to the first light blocking part BM-1. In one direction or in a direction perpendicular to the thickness direction DR3, a length of the first bottom surface B1_DF of the first light blocking part BM-1 and a length of the second bottom surface B2_DF of the second light blocking part BM-2 may be substantially the same.

The second side surface B2_SF may be inclined with respect to the second bottom surface B2_DF and the top surface B2_UF. A first angle θ1 between the second side surface B2_SF and the second bottom surface B2_DF may be greater than about 90° and less than or equal to about 160°. A second angle θ2 between the second side surface B2_SF and the top surface B2_UF may be greater than about 0° and less than about 90º. The second light blocking part BM-2, in which the first angle θ1 between the second side surface B2_SF and the second bottom surface B2_DF is greater than about 90° and less than or equal to about 160°, may have a substantially inverse taper shape in cross-section. The second light blocking part BM-2 that satisfies the above-described angle range may absorb external light or guide a path of the external light to the first light blocking part BM-1. The second light blocking part BM-2 that satisfies the above-described angle range may facilitate the transmission of light emitted from the light emitting element ED (see FIG. 5).

The refractive index of the filter part CF may be about 1.4. The refractive index of the second light blocking part BM-2 may be about 1.5 or more and less than about 1.8. In case that calculating the first angle θ1 at which total reflection of the external light is possible using Snell's law, approximately about 140° to about 160° may be derived. In an angle range of about 140° to about 160°, total reflection of the external light may occur, and in an angle range of about 90° to about 140°, the optical path of the external light may be guided into the second light blocking part BM-2 to absorb the external light. Thus, the display device DD (see FIG. 1) including the second light blocking part BM-2 in which the first angle θ1 between the second side surface B2_SF and the second bottom surface B2_DF is greater than about 90° and less than or equal to about 160° may exhibit excellent display quality.

The thickness TH of the light blocking pattern BMP may be about 0.5 um or more and about 2.0 μm or less. The thickness TH of the light blocking pattern BMP may be the sum of the first thickness TN1 of the first light blocking part BM-1 and the second thickness TN2 of the second light blocking part BM-2. A ratio of the first thickness TN1 of the first light blocking part BM-1 to the second thickness TN2 of the second light blocking part BM-2 is about 1:0.5 to about 1:2.0. In case that the thickness TH of the light blocking pattern BMP is less than about 0.5 μm, an external light absorption rate of the light blocking pattern BMP may decrease to deteriorate the display quality. In case that the thickness TH of the light blocking pattern BMP exceeds about 2.0 μm, the transmission of light (for example, first to third light) emitted from the light emitting element ED (see FIG. 5) may be reduced to deteriorate the display efficiency. On the other hand, in one embodiment, the light blocking pattern BMP having a thickness TH of about 0.5 μm or more and about 2.0 μm or less may have a high external light absorption rate and allow light emitted from the light emitting element ED (see FIG. 5) to be transmitted through the display device DD (see FIG. 2), thereby improving the display quality and the display efficiency.

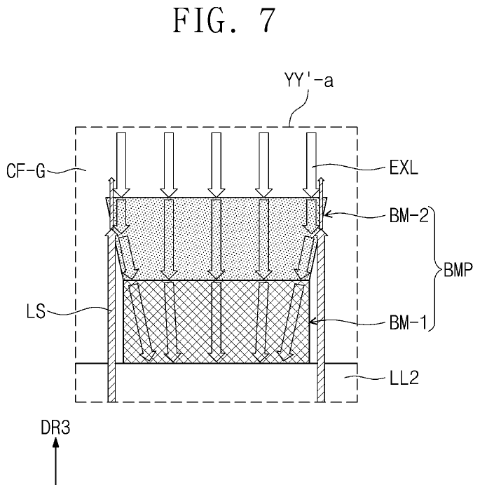

FIG. 7 is an enlarged schematic cross-sectional view of an area YY′-a of FIG. 6. FIG. 7 illustrates a light blocking pattern BMP disposed on the emission area PXA (see FIG. 5). FIG. 7 illustrates a path of light EXL incident from the outside of the display device DD (see FIG. 1) and a path of light LS emitted from the light emitting element ED (see FIG. 5). As described with reference to FIG. 6, the first and second light blocking units BM-1 and BM-1, which satisfy the refractive index, the optical density, the thicknesses TN1 and TN2, and the angles θ1 and θ2 according to an embodiment, may absorb the light EXL entering from the outside of the display device DD (see FIG. 1) and transmit the light LS emitted from the light emitting element ED (see FIG. 5) to the display device DD (see FIG. 1) to improve the display quality.

In an embodiment, the refractive index of the first light blocking part BM-1 (see FIG. 6) may be greater than the refractive index of the second light blocking part BM-2 (see FIG. 6). The refractive index of the first light blocking part BM-1 (see FIG. 6) may be about 1.8 or more and about 2.5 or less, and the refractive index of the second light blocking part BM-2 (see FIG. 6) may be about 1.5 or more and less than about 1.8. The optical density of the first light blocking part BM-1 (see FIG. 6) may be greater than that of the second light blocking part BM-2 (see FIG. 6). The optical density of the first light blocking part BM-1 (see FIG. 6) may be about 1.5 or more and about 2.0 or less, and the optical density of the second light blocking part BML-2 (see FIG. 6) may be about 1.0 or more and less than about 1.5. The thickness TH (see FIG. 6) of the light blocking pattern BMP (see FIG. 6), which is obtained by adding the first thickness TN1 (see FIG. 6) of the first light blocking part BM-1 (see FIG. 6) and the second thickness TN2 (see FIG. 6) of the second light blocking part BM-2 (see FIG. 6) may be about 0.5 μm or more and about 2.0 μm or less. A ratio of the first thickness TN1 (see FIG. 6) of the first light blocking part BM-1 (see FIG. 6) to the second thickness TN2 (see FIG. 6) of the second light blocking part BM-2 (see FIG. 6) is about 1:0.5 to about 1:2.0.

FIG. 8 is a schematic sectional view of an emission layer according to an embodiment. FIG. 8 may be a schematic cross-sectional view illustrating a display module DM-1 according to an embodiment. Hereinafter, in the description in FIG. 8, contents overlapping with those described with reference to FIGS. 1 to 7 will not be described again, and differences will be described.

In case that compared to the display module DM illustrated in FIG. 5, a display module DM-1 illustrated in FIG. 8 is different in that the display module DM-1 further includes an inorganic deposition layer IDL. The inorganic deposition layer IDL may be disposed on a light emitting element ED. An encapsulation layer TFE may be disposed on the inorganic deposition layer IDL.

The inorganic deposition layer IDL may be disposed on a capping layer CPL. The inorganic deposition layer IDL may be disposed directly on the capping layer CPL. The inorganic deposition layer IDL may be a layer to prevent external light from being reflected by a second electrode EL2 of the light emitting element ED. For example, destructive interference may occur between light reflected from a surface of an inorganic deposition layer IDL and light reflected from the second electrode EL2 to reduce an amount of external light reflected from the surface of the second electrode EL2. A thickness of the inorganic deposition layer IDL and the capping layer CPL may be adjusted so that destructive interference occurs between the light reflected from the surface of the inorganic deposition layer IDL and the light reflected from the second electrode EL2.

The inorganic deposition layer IDL may include an inorganic material having a refractive index of about 1.0 or more and a light absorption coefficient of about 0.5 or more. The inorganic vapor deposition layer IDL may be formed through a thermal evaporation process and may be made of an inorganic material with a melting point of about 1,000° C. or lower. For example, the inorganic deposition layer IDL may include at least one of bismuth (Bi) and ytterbium (Yb). Bismuth (Bi) or ytterbium (Yb) may be provided to form the inorganic deposition layer IDL, or YbxBiy that is a mixed deposition material of bismuth and ytterbium may be provided.

A display device according to an embodiment may include an optical layer disposed on a display element layer. The optical layer may include a light blocking pattern constituted by a first light blocking pattern overlapping an emission area and a second light blocking pattern overlapping a non-emission area. Each of the first light blocking pattern and the second light blocking pattern may include a first light blocking part and a second light blocking part disposed on the first light blocking part. In the cross-section, the first light blocking part may have a rectangular shape, and the second light blocking part may have a substantially inverse taper shape. The first light blocking part may include a first bottom surface and a first side surface substantially perpendicular to the first bottom surface, and the second light blocking part may include a second bottom surface and a second side surface inclined with respect to the second bottom surface. The refractive index of the first light blocking part may be greater than that of the second light blocking part, and the optical density of the first light blocking part may be greater than the optical density of the second light blocking part. Thus, the display device according to an embodiment including the light blocking pattern may reduce external light reflection and exhibit excellent display efficiency.

The display device according to the embodiment may include the first light blocking part and the second light blocking part, which have the different optical characteristics and shapes, to reduce the external light reflection and exhibit the excellent display efficiency.

It will be apparent to those skilled in the art that various modifications and deviations can be made in the disclosure. Thus, it is intended that the disclosure covers the modifications and deviations of this disclosure provided they come within the scope of the appended claims and their equivalents.

Therefore, the technical scope of the disclosure is not limited to the contents described in the detailed description of the specification, but should be also determined by the claims.

What is claimed is:

1. A display device comprising:
a display element layer comprising a light emitting element and a pixel defining layer including a pixel opening; and
an optical layer comprising a light blocking pattern, the light blocking pattern comprises a first light blocking part and a second light blocking part disposed on the first light blocking part, and disposed on the display element layer, wherein
the first light blocking part comprises a first bottom surface spaced apart from the second light blocking part and a first side surface substantially perpendicular to the first bottom surface,
the second light blocking part comprises a second bottom surface adjacent to the first light blocking part and a second side surface inclined with respect to the second bottom surface, and
an angle between the second bottom surface and the second side surface is greater than about 90° and less than or equal to about 160°.

2. The display device of claim 1, wherein a refractive index of the first light blocking part is greater than a refractive index of the second light blocking part.

3. The display device of claim 1, wherein a refractive index of the first light blocking part is about 1.8 or more and about 2.5 or less.

4. The display device of claim 1, wherein a refractive index of the second light blocking part is about 1.5 or more and less than about 1.8.

5. The display device of claim 1, wherein an optical density (OD) of the first light blocking part is greater than an optical density of the second light blocking part.

6. The display device of claim 1, wherein an optical density of the first light blocking part is about 1.5 or more and about 2.0 or less.

7. The display device of claim 1, wherein an optical density of the second light blocking part is about 1.0 or more and less than about 1.5.

8. The display device of claim 1, wherein a sum of a first thickness of the first light blocking part and a second thickness of the second light blocking part is about 0.5 μm or more and about 2.0 μm or less.

9. The display device of claim 1, wherein a ratio of a first thickness of the first light blocking part to a second thickness of the second light blocking part is in a range of about 1:0.5 to about 1:2.0.

10. The display device of claim 1, wherein
the light emitting element comprises:
a first electrode of which at least a portion is partially exposed in the pixel opening;
a second electrode facing the first electrode; and
an emission layer disposed between the first electrode and the second electrode,
the light blocking pattern comprises a first light blocking pattern overlapping the emission layer and a second light blocking pattern overlapping the pixel defining layer, and
each of the first light blocking pattern and the second light blocking pattern comprises the first light blocking part and the second light blocking part.

11. The display device of claim 10, wherein the first light blocking pattern has a substantially circular or substantially square shape in a plan view.

12. The display device of claim 1, wherein
the light blocking pattern includes a pattern opening, and
the optical layer further comprises a filter part comprising at least one of a pigment and a dye and filled into the pattern opening of the light blocking pattern.

13. The display device of claim 12, wherein
the display device comprises an emission area and a non-emission area adjacent to the emission area, and
the filter part in the emission area covers the light blocking pattern.

14. The display device of claim 13, wherein
the filter part in the emission area comprises a first portion overlapping the light blocking pattern and a second portion that does not overlap the light blocking pattern, and
a first height of the first portion is higher than a second height of the second portion in a thickness direction.

15. A display device comprising:
an emission area and a non-emission area adjacent to the emission area;
a display element layer comprising a light emitting element and a pixel defining layer including a pixel opening; and
an optical layer comprising a first light blocking pattern in the emission area and a second light blocking pattern in the non-emission area, wherein
each of the first light blocking pattern and the second light blocking pattern comprises a first light blocking part and a second light blocking part disposed on the first light blocking part, and
an optical density (OD) of the first light blocking part is greater than an optical density of the second light blocking part, and a refractive index of the first light blocking part is greater than a refractive index of the second light blocking part.

16. The display device of claim 15, wherein
the first light blocking part comprises a first bottom surface spaced apart from the second light blocking part and a first side surface substantially perpendicular to the first bottom surface,
the second light blocking part comprises a second bottom surface adjacent to the first light blocking part and a second side surface inclined with respect to the second bottom surface, and
an angle between the second bottom surface and the second side surface is greater than about 90° and less than or equal to about 160°.

17. The display device of claim 15, wherein
the optical density of the first light blocking part is about 1.5 or more and about 2.0 or less, and
the optical density of the second light blocking part is about 1.0 or more and less than about 1.5.

18. The display device of claim 15, wherein
the refractive index of the first light blocking part is about 1.8 or more and about 2.5 or less, and
the refractive index of the second light blocking part is about 1.5 or more and less than about 1.8.

19. The display device of claim 15, wherein
a sum of a first thickness of the first light blocking part and a second thickness of the second light blocking part is about 0.5 μm or more and about 2.0 μm or less, and
a ratio of the first thickness of the first light blocking part to the second thickness of the second light blocking part is in a range of about 1:0.5 to about 1:2.0.

20. The display device of claim 15, wherein the optical layer further comprises a filter part comprising at least one of a pigment and a dye and covering the first light blocking pattern.
